(19) United States
(12) Patent Application Publication
(10) Pub. No.: US 2022/0075258 A1
(43) Pub. Date: Mar. 10, 2022

(54) BLANKMASK AND PHOTOMASK

(71) Applicant: S&S TECH Co., Ltd., Daegu-si (KR)

(72) Inventors: Cheol SHIN, Daegu-si (KR); Jong-Hwa LEE, Daegu-si (KR); Chul-Kyu YANG, Daegu-si (KR); Min-Ki CHOI, Daegu-si (KR); Seung-Hyup SHIN, Daegu-si (KR); Gil-Woo KONG, Daegu-si (KR)

(73) Assignee: S&S TECH Co., Ltd., Daegu-si (KR)

(21) Appl. No.: 17/418,467

(22) PCT Filed: Dec. 20, 2019
(86) PCT No.: PCT/KR2019/018175

§ 371 Date: Jun. 25, 2021

(30) Foreign Application Priority Data
Dec. 26, 2018 (KR) 10-2018-0168941
Mar. 7, 2019 (KR) 10-2019-0026066

(51) Int. Cl. G03F 1/48; G03F 1/32

(52) U.S. Cl. CPC G03F 1/48; G03F 1/32

(57) ABSTRACT

A blankmask includes a hard film and a light-shielding film formed on a transparent substrate. The hard film is made of a silicon compound that contains at least one of oxygen, nitrogen and carbon in addition to silicon. There are provided a blankmask and a photomask improved in resolution, desired critical dimension (CD), and process window margin. Thus, it is possible to manufacture a blankmask and a photomask of good quality when a pattern of 32 nm or below, in particular, 14 nm or below is formed.

### BACKGROUND

### Field

The disclosure relates to a blankmask and a photomask, and more particularly to a blankmask and a photomask, in which a fine pattern of 32 nm or below, in particular, 14 nm or below can be formed, and a hard film is provided.

### Description of the Related Art

Nowadays, demands for miniaturization of a circuit pattern have been continued according to high integration of a large-scale integrated circuit. In a case of a blankmask, a blankmask for a hard mask provided with a hard film has recently been developed and used.

The blankmask for the hard mask provided with the hard film has merits as follows. First, the hard film makes it possible to make a resist film formed thereon thinner, thereby playing an effective role in improving resolution. Specifically, as the resist film becomes thinner, it is easier to enhance and control the resolution because electrons scatter less when the thin resist film is exposed to an electron-beam (or e-beam). Further, the hard film is so thin that a loading effect can be decreased while a hard film pattern is formed, and a loading effect can also be remarkably decreased while a light-shielding film pattern is formed beneath the hard film by using the hard film as an etching mask, thereby having an effect on ultimately improving a critical dimension (CD) characteristic when the mask is manufactured.

Such a hard film employed in the blankmask is made of chrome (Cr) or a chrome compound or made of silicon (Si) or a silicon compound. In general, a binary blankmask has employed chrome (Cr) or the chrome compound as a material for the hard film, and a phase-shift blankmask has employed silicon (Si) or the silicon compound as a material for the hard film. All these materials described above are excellent in etch selectivity to the light-shielding film formed therebeneath.

Meanwhile, with development of semiconductor technology, there have recently been processed semiconductor devices of 32 nm or below, 14 nm or below, and in particular 7 nm or below. In this regard, there have arisen various problems which were not taken into account in the past. For example, for not only the resolution but also qualities of a photomask, such as CD control, line edge roughness (LER) and CD linearity, large process window margin and the like are required. With respect to such requirements, the blankmask using a conventional hard film, in particular, the blankmask using the hard film made of silicon or the silicon compound has problems as follows. The silicon (Si)-based hard film is rapidly etched when fluorine (F)-based etching gas is used. Therefore, the process window margin is small when the hard film pattern is formed. In detail, rapid etching makes it difficult to perform end point detection (EPD), examine a pattern profile, control CD accuracy, etc.

### SUMMARY

Accordingly, an aspect of the disclosure is to the disclosure a blankmask and a photomask which are improved in a desired critical dimension (CD) characteristic and a process window margin as well as resolution of the photomask by properly controlling materials of a hard film and a composition ratio of the materials. With this, there are provided a blankmask and a photomask which have good quality when a pattern of 32 nm or below, in particular, 14 nm or below is formed.

According to one embodiment of the disclosure, there is provided a blankmask including a transparent substrate, a light-shielding film formed on the transparent substrate, and a hard film formed on the light-shielding film, the hard film including a silicon compound that contains a light element among at least one of oxygen, nitrogen and carbon in addition to silicon.

In the hard film, a silicon content may be 50 at % or lower, and a content of the light element may be 50 at % or higher. Preferably, in the hard film, a silicon content may be 30 at % or lower, and a content of the light element may be 70 at % or higher.

The hard film may include an oxygen content of 40 at % or higher. Preferably, the hard film may include an oxygen content of 50 at % or higher.

The hard film may have a thickness of 2 nm to 20 nm.

The light-shielding film may include chrome; a compound that contains chrome and the light element; a compound that contains chrome and metal; or a compound that contains chrome, metal and the light element.

The light-shielding film may include a multi-layered film of two or more layers. In this case, one or more layers below a topmost layer of the light-shielding film may be configured to be more rapidly etched than the topmost layer when the resist film includes a positive resist, and one or more layers below a topmost layer of the light-shielding film may be configured to be more slowly etched than the topmost layer when the resist film includes a negative resist.

An etching speed for each layer of the light-shielding film is controlled by adjusting content of the light element contained in each layer.

On the transparent substrate, a phase-shift film may be formed.

The phase-shift film may include a silicon compound or a compound that contains silicon and molybdenum.

The phase-shift film may include a transmissivity of 5% to 50% with respect to exposure light having a wavelength of 193 nm, and a phase shift of 170 to 190 degrees.

According to one embodiment of the disclosure, there is provided a photomask manufactured using the foregoing blankmask.

### BRIEF DESCRIPTION OF THE DRAWINGS

The above and/or other aspects will become apparent and more readily appreciated from the following description of exemplary embodiments, taken in conjunction with the accompanying drawings, in which

FIG. 1 is a cross-sectional view of a phase-shift blankmask according to an embodiment of the disclosure.

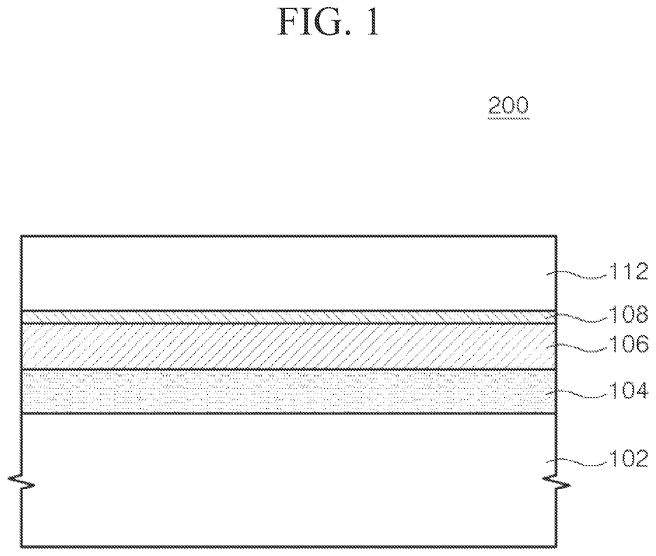

### DETAILED DESCRIPTION OF EXEMPLARY EMBODIMENTS

Although embodiments of the disclosure will be described below in detail with reference to the accompanying drawings, the embodiments are provided for illustrative purpose only and should not be construed to limit the meaning or scope of the disclosure described in the appended claims. Therefore, it will be appreciated by a person having an ordinary skill in the art that various modifications and equivalents can be made from the embodiments. Further, the true technical scope of the disclosure should be defined by technical details of the appended claims.

A blankmask according to the disclosure refers to a blankmask with a hard film made of silicon or a silicon compound. The hard film made of such a material is generally used for a phase-shift blankmask.

A blankmask 200 includes a phase-shift film 104, a light-shielding film 106, a hard film 108, and a resist film 112, which are formed in sequence on a transparent substrate 102. The hard film 108 is disposed between the light-shielding film 106 and the resist film 112, and functions as an etching mask form forming a pattern of the light-shielding film 106.

The hard film 108 is made of the silicon compound that contains one or more kinds of light elements among oxygen (O), nitrogen (N) and carbon (C) in addition to silicon (Si).

In particular, a silicon content of the hard film 108 is 50 at % or lower, and preferably 30 at % or lower. Further, a light-element content is 50 at % or higher, and preferably 70 at % or higher. Especially, an oxygen (O) content in the light element content of the hard film 108 is 40 at % or higher, and preferably 50 at % or higher.

The hard film 108 may be made of a material having an etch selectivity to the light-shielding film 106 formed beneath the hard film 108. Because silicon (Si) is rapidly etched by fluorine-based gas but slowly etched by chlorine-based gas, the silicon (Si) content of the hard film 108 is 5 at % or higher, and preferably 10 at % or higher, to have an etch selectivity of ‘10’ or higher to the light-shielding film 106.

Meanwhile, when the silicon content becomes higher, silicon is more rapidly etched, and thus it is difficult to detect an end point at the etching. Therefore, the silicon content is 50 at % or lower, and preferably 30 at % or lower. Thus, a light-element content of the hard film 108, e.g. the total content of oxygen, nitrogen and carbon is not higher than 50 at % to 70 at %. In particular, oxygen among the light elements may be controlled as follows.

The hard film 108 needs to have strong adhesion with the resist film 112 formed thereon, and the importance of the adhesion is increasing as the size of a desired pattern becomes smaller. When the hard film 108 made of the silicon compound has an oxygen content of 40 at % or lower, the hard film 108 shows relatively hydrophilic properties and thus the adhesion between the hard film 108 and the resist film is weakened. Therefore, the oxygen content of the hard film 108 is 40 at % or higher, and preferably 50 at % or higher, thereby enhancing the adhesion between the hard film 108 and the resist film.

Meanwhile, the hard film 108 made of the silicon compound is noticeably rapidly etched by the fluorine (F)-based gas. Further, the hard film is achieved by a thin film of 20 nm or below, and preferably 15 nm or below, and it is this difficult to do end point detection (EPD). Therefore, a slowdown is required in etching the silicon (Si)-based hard film 108 under the fluorine (F)-based gas. To this end, the disclosure proposes a method of decreasing the silicon (Si) content and increasing the oxygen (O)-content to thereby achieve the slowdown in etching the hard film 108. Therefore, the silicon content of the hard film 108 may be 50 at % or lower, and preferably 30 at % or lower. Thus, process control is effectively carried out.

The hard film 108 formed as described above has a thickness of 2 nm to 20 nm, and preferably 5 nm to 15 nm. When the thickness is less than or equal to 2 nm, it is difficult to control at the etching process. When the thickness is greater than or equal to 20 nm, it is possible to control the etching speed, but the loading effect increases which results in bad CD control.

The hard film 108 may have a single layer or a multi-layer having two or more layers. Alternatively, the hard film 108 may be formed as a continuous film or a single film. The hard film 108 is formed by one or more methods among physical vapor deposition (PVD), chemical vapor deposition (CVD), and atomic layer deposition (ALD), and preferably formed by a sputtering method.

The light-shielding film 106 beneath the hard film 108 has an optical density of 2.5 to 3.5 at an exposure-light wavelength of 193 nm.

The light-shielding film 106 may include one or more kinds of material selected among chrome (Cr), silicon (Si), molybdenum (Mo), tantalum (Ta), vanadium (V), cobalt (Co), nickel (Ni), zirconium (Zr), niobium (Nb), palladium (Pd), zinc (Zn), aluminum (Al), manganese (Mn), cadmium (Cd), tin (Sn), magnesium (Mg), lithium (Li), selenium (Se), copper (Cu), hafnium (Hf) and tungsten (W), or may include a compound that contains one or more kinds of light elements among oxygen, nitrogen and carbon in addition to the selected material. Preferably, the light-shielding film 106 may include chrome, a compound that contains chrome and a light element, a compound that contains chrome and metal, or a compound that contains chrome, metal and a light element.

The light-shielding film 106 may have a single layer or a multi-layer having two or more layers, and may have a thickness of 30 nm to 70 nm.

According to the kinds of resist applied to the top of the light-shielding film 106, for example, according to whether the resist is positive or negative, the light-shielding film 106 may be designed as follows.

First, when the positive resist is used, one or more layers below the topmost layer of the light-shielding film 106 are designed to be more rapidly etched than the topmost layer so that the light-shielding film 106 can be patterned better. Thus, it is possible to prevent a footing phenomenon.

Meanwhile, when the negative resist is used, one or more layers below the topmost layer of the light-shielding film 106 are designed to be more slowly etched than the topmost layer so that the light-shielding film 106 can be patterned better. Thus, it is possible to prevent an undercut phenomenon.

To this end, the etching speed for each layer of the light-shielding film 106 may be controlled by adjusting the content of light elements such as oxygen (O), nitrogen (N) and carbon (C) in each layer.

The phase-shift film 104 may include one or more kinds of material selected among chrome (Cr), silicon (Si), molybdenum (Mo), tantalum (Ta), vanadium (V), cobalt (Co), nickel (Ni), zirconium (Zr), niobium (Nb), palladium (Pd), zinc (Zn), aluminum (Al), manganese (Mn), cadmium (Cd), tin (Sn), magnesium (Mg), lithium (Li), selenium (Se), copper (Cu), hafnium (Hf) and tungsten (W), or may include a compound that contains one or more kinds of light elements among oxygen, nitrogen and carbon in addition to the selected material. Preferably, the phase-shift film 104 may include a compound that contains oxygen, nitrogen, carbon or the like light element in addition to silicon or molybdenum silicon.

The phase-shift film 104 has a transmissivity of 5% to 50% with respect to an exposure-light wavelength of 193 nm, and a phase shift of 170 degrees to 190 degrees. Specifically, the phase-shift film 104 may be manufactured to have transmissivities of 6%, 12%, 18%, 24%, 30%, etc. for its purposes, and corresponding phase shifts of 170 degrees, 175 degrees, 180 degrees, 185 degrees, 190 degrees, etc. Like this, the phases of the thin film are controlled by taking over-etching into account. In particular, the phase-shift blankmask with the hard film 108 configured as described above may have a transmittivity less than 6% to 30%.

### Embodiment #1: Method of Manufacturing Phase-Shift Blankmask with Hard Film

The embodiment #1 describes a method of manufacturing a phase-shift blankmask with a hard film and a photomask.

A phase-shift film, a light-shielding film, a hard film, and a resist film were sequentially formed on a transparent substrate. A concave transparent substrate having a total indicated reading (TIR) value of −82 nm when flatness is defined by TIR was used.

The phase-shift film was manufactured by a monocrystal method. A single-wafer type DC magnetron sputtering system mounted with a target of silicon (Si) having purity of 7N and doped with boron (B) was injected with process gas of Ar:N₂:NO=5 sccm:5 sccm:5.3 sccm, and supplied with process power of 1.0 kW, thereby forming an SiON film having a thickness of 125 nm. As results of measuring the transmissivity and the phase shift of such a formed phase-shift film through the n&k Analyzer 3700RT, the phase-shift film showed a transmissivity central value of 68% and a phase shift central value of 205′ with respect to a wavelength of 193 nm. Further, as a result of measuring the flatness, the phase-shift film showed a convex shape having a value of +80 nm. Further, as a result of analyzing the composition ratio of the phase-shift film through Auger electron spectroscopy (AES), the phase-shift film showed the composition ratio of silicon (Si):nitrogen (N):oxygen (O)=16.3 at %:15.6 at %:68.1 at %.

Then, the phase-shift film was thermally processed by a vacuum rapid thermal processing (RTP) system at a temperature of 500° C. for 40 minutes to thereby improve the flatness. As a result of measuring the stress of the phase-shift film, the phase-shift film showed a convex shape having a value of +30 nm, and the stress change (i.e. delta stress) of the whole phase-shift film was +112 nm. Thus, it is understood that the stress is released by the thermal processing.

To form the light-shielding film, the single-wafer type DC magnetron sputtering system mounted with a target of chrome (Cr) was injected with process gas of Ar:N₂:CH₄=5 sccm:12 sccm:0.8 sccm, and supplied with process power of 1.4 kW, thereby forming a lower film of CrCN having a thickness of 43 nm. Then, an upper film of CrON having a thickness of 16 nm was formed by injecting process gas of Ar:N₂:NO=3 sccm:10 sccm:5.7 sccm, and supplying process power of 0.62 kW, thereby forming the light-shielding film having a two-layered structure.

Thereafter, as results of measuring the optical density and the reflectivity of the light-shielding film, the light-shielding film showed an optical density of 3.10 and a reflectivity of 29.6% with respect to exposure light having a wavelength of 193 nm. Therefore, it is understood that the measured optical-density and reflectivity are suitable for those of the light-shielding film.

To form the hard film, the single-wafer type DC magnetron sputtering system mounted with a target of silicon (Si) was injected with process gas of Ar:N₂:NO=7 sccm:7 sccm:5 sccm, and supplied with process power of 0.7 kW, thereby forming a SiON film having a thickness of 10 nm.

Next, the hard film was subjected to a hexa-methyl-di-silazane (HDMS) process, and then a chemically amplified negative resist was formed to have a thickness of 100 nm by a spin coating system, thereby completely manufacturing the phase-shift blankmask.

The blankmask manufactured as described above was subjected to an exposure process, and then subjected to a post exposure bake (PEB) process at a temperature of 100 degrees for 10 minutes and developed to form a resist film pattern. Then, the lower hard film was dry-etched with fluorine (F)-based gas by using the resist film pattern as the etching mask, thereby forming a hard film pattern. In this case, as a result of measuring an etching end of the hard film through an EPD system, the etching end showed 17 seconds.

After removing the resist film pattern, the lower light-shielding film was etched by employing the hard film pattern as the etching mask, thereby forming a light-shielding film pattern. Meanwhile, the light-shielding film may be etched by employing both the resist film and the hard film as the etching masks.

While using the hard film pattern and the light-shielding film pattern as the etching masks, the lower phase-shift film was dry-etched with fluorine (F)-based gas to thereby form a phase-shift film pattern.

In this case, as a result of analyzing the etching end of the phase-shift film pattern through the EPD system, it was possible to distinguish the etching end because the phase-shift film pattern employed a nitrogen (N) peak on the contrary to the lower transparent substrate. Here, the hard film pattern was entirely removed at the etching for forming the phase-shift film pattern.

After forming a secondary resist film pattern on the transparent substrate formed with the phase-shift film pattern, the light-shielding film pattern was removed in an exposed main area except an outer circumferential area, thereby ultimately completing the phase-shift photomask.

With respect to the phase-shift photomask manufactured as described above, the pure transmissivity and phase shift of the phase-shift film pattern were measured through an MPM-193 system. In result, the transmissivity was 72.3% and the phase shift was 215° at the wavelength of 193 nm. Further, a pattern profile was 86° as a result of being observed through a transmission electron microscope (TEM).

### Embodiments #2-5/Comparative Examples #1 & 2: Evaluation Results of Etching Speed According to Composition Ratios of Hard Film

In the embodiments #2˜5 and the comparative examples #1 and 2, the etching speed and chemical resistance of the phase-shift blankmask with the hard film were evaluated while changing the film composition ratio of the hard film, and results of the evaluation are shown in the Table 1 below.

TABLE 1

| | Embodiment | | Embodiment | | Embodiment | | Embodiment | | Comparative | | Comparative | |
|---|---|---|---|---|---|---|---|---|---|---|---|---|
| | #2 | | #3 | | #4 | | #5 | | example # 1 | | example # 2 | |
| Sputter Target | Si | | Si | | Si | | Si | | Si | | Si | |
| Composition ratio | 21:75:4 | | 23:74:3 | | 28:69:3 | | 42:48:10 | | 53:0:47 | | 65:0:34 | |
| (Si:O:N) | | | | | | | | | | | | |
| Etching speed at | 9.09 | Å/sec | 9.23 | Å/sec | 9.52 | Å/sec | 11.3 | Å/sec | 15.6 | Å/sec | 13.5 | Å/sec |
| fluorine-based etching | | | | | | | | | | | | |
| Thickness damage at | −4.3 | Å | −4.8 | Å | −5.2 | Å | −8.2 | Å | −1.2 | Å | −0.9 | Å |
| chlorine-based etching | | | | | | | | | | | | |

Table 1 shows evaluation results of etching speed under fluorine-based gas and thickness damage under chlorine-based gas according to the composition ratios of the hard film formed in the phase-shift blankmask.

In result, first the lower the oxygen content of the hard film was, the higher the etching speed was. The comparative examples #1 and #2 showed that it took 6 to 8 seconds to etch the hard film having a thickness of 10 nm, and change more than 10% was made when over etching time is identified in seconds, thereby causing a problem that etching control is difficult.

According to the disclosure, there are provided a blankmask and a photomask improved in resolution, desired CD characteristics, and process window margin. Thus, it is possible to manufacture a blankmask and a photomask of good quality when a pattern of 32 nm or below, in particular, 14 nm or below is formed.

Although the disclosure has been shown and described with exemplary embodiments, the technical scope of the disclosure is not limited to the scope disclosed in the foregoing embodiments. Therefore, it will be appreciated by a person having an ordinary skill in the art that various changes and modifications may be made from these exemplary embodiments. Further, it will be apparent as defined in the appended claims that such changes and modifications are involved in the technical scope of the disclosure.

1. A blankmask comprising a transparent substrate, a light-shielding film formed on the transparent substrate, and a hard film formed on the light-shielding film,
the hard film comprising a silicon compound that contains a light element among at least one of oxygen, nitrogen and carbon in addition to silicon.

2. The blankmask according to claim 1, wherein in the hard film, a silicon content is 50 at % or lower, and a content of the light element is 50 at % or higher.

3. The blankmask according to claim 1, wherein in the hard film, a silicon content is 30 at % or lower, and a content of the light element is 70 at % or higher.

4. The blankmask according to claim 2, wherein the hard film comprises an oxygen content of 40 at % or higher.

5. The blankmask according to claim 2, wherein the hard film comprises an oxygen content of 50 at % or higher.

6. The blankmask according to claim 1, wherein the hard film has a thickness of 2 nm to 20 nm.

7. The blankmask according to claim 1, wherein the light-shielding film comprises chrome; a compound that contains chrome and the light element; a compound that contains chrome and metal; or a compound that contains chrome, metal and the light element.

8. The blankmask according to claim 1, wherein
the light-shielding film comprises a multi-layered film of two or more layers,
when a resist film comprises a positive resist, one or more layers below a topmost layer of the light-shielding film are configured to be more rapidly etched than the topmost layer.

9. The blankmask according to claim 1, wherein
the light-shielding film comprises a multi-layered film of two or more layers,
when a resist film comprises a negative resist, one or more layers below a topmost layer of the light-shielding film are configured to be more slowly etched than the topmost layer.

10. The blankmask according to claim 8, wherein an etching speed for each layer of the multi-layered film of the light-shielding film is controlled by adjusting content of the light element contained in each layer.

11. The blankmask according to claim 1, further comprising a phase-shift film formed on the transparent substrate.

12. The blankmask according to claim 11, wherein the phase-shift film comprises a silicon compound or a compound that contains silicon and molybdenum.

13. The blankmask according to claim 11, wherein the phase-shift film comprises a transmissivity of 5% to 50% with respect to exposure light having a wavelength of 193 nm, and a phase shift of 170 to 190 degrees.

14. A photomask manufactured using the blankmask according to claim 1.
